(19) United States
(12) Patent Application Publication
(10) Pub. No.: US 2025/0022837 A1
(43) Pub. Date: Jan. 16, 2025

(54) WIRE BONDING APPARATUS

(71) Applicant: Samsung Electronics Co., Ltd., Suwon-si (KR)

(72) Inventors: Doojin KIM, Suwon-si (KR); Byongjoo KIM, Suwon-si (KR)

(73) Assignee: Samsung Electronics Co., Ltd., Suwon-si (KR)

(21) Appl. No.: 18/524,828

(22) Filed: Nov. 30, 2023

(30) Foreign Application Priority Data
Jul. 13, 2023 (KR) 10-2023-0090832

(51) Int. Cl. H01L 23/00

(52) U.S. Cl. CPC H01L 24/78; H01L 2224/78251; H01L 2224/7855; H01L 2224/7865

(57) ABSTRACT

A wire bonding apparatus may include a bonder and a common loader/unloader. The bonder may bond a conductive wire to a plurality of package substrates. The common loader/unloader may load the package substrates into the bonder. The common loader/unloader may unload the package substrates from the bonder. Thus, an occupying area of the wire bonding apparatus in semiconductor fabrication equipment may be reduced to improve a productivity of the semiconductor fabrication equipment.

### CROSS-REFERENCE TO RELATED APPLICATION

This application claims priority under 35 USC § 119 to Korean Patent Application No. 10-2023-0090832, filed on Jul. 13, 2023 in the Korean Intellectual Property Office (KIPO), the contents of which are herein incorporated by reference in their entirety.

### BACKGROUND

### 1. Field

Example embodiments relate to wire bonding apparatuses. More particularly, example embodiments relate to wire bonding apparatuses configured to bond a conductive wire to a package substrate.

### 2. Description of the Related Art

A plurality of semiconductor chips may be stacked on a package substrate. The semiconductor chips and the package substrate may be electrically connected with each other via conductive wires. The conductive wires may be bonded to the package substrate using a wire bonding apparatus.

According to related arts, the wire bonding apparatus may include a loader, a bonder and an unloader. The loader and the unloader may be positioned at both sides of the bonder. That is, the loader, the bonder and the unloader may be arranged in a row.

Thus, the wire bonding apparatus may have a long length. The wire bonding apparatus having the long length may occupy a large area in semiconductor fabrication equipment. As a result, a productivity of the semiconductor fabrication equipment by an area may be decreased.

### SUMMARY

Some example embodiments of the inventive concepts provide a wire bonding apparatus having a small occupying area in semiconductor fabrication equipment.

According to some example embodiments, there may be provided a wire bonding apparatus. The wire bonding apparatus may include a bonder and a common loader/unloader. The bonder may bond a conductive wire to a plurality of package substrates. The common loader/unloader may load the plurality of package substrates into the bonder. The common loader/unloader may unload the plurality of package substrates from the bonder.

According to some example embodiments, there may be provided a wire bonding apparatus. The wire bonding apparatus may include a first bonder, a second bonder and a common loader/unloader. The first bonder may bond a first article of a conductive wire to a first package substrate. The second bonder may bond a second article of a conductive wire to a second package substrate. The common loader/unloader may be between the first bonder and the second bonder. The common loader/unloader may load the first and second package substrates into the first and second bonders. The common loader/unloader may unload the first and second package substrates from the first and second bonders.

According to some example embodiments, there may be provided a wire bonding apparatus. The wire bonding apparatus may include a first bonder, a second bonder and a common loader/unloader. The first bonder may bond a first article of a conductive wire to a first package substrate. The second bonder may bond a second article of the conductive wire to a second package substrate. The common loader/unloader may be at a rear region of the first bonder and the second bonder. The common loader/unloader may load the first and second package substrates into the first and second bonders. The common loader/unloader may unload the first and second package substrates from the first and second bonders.

According to some example embodiments, the single common loader/unloader may load the package substrate into the bonder and unload the package substrate from the bonder. The common loader/unloader may be positioned at one side of the bonder so that the wire bonding apparatus may have a short length. As a result, an occupying area of the wire bonding apparatus in semiconductor fabrication equipment may be reduced to improve a productivity of the semiconductor fabrication equipment.

### BRIEF DESCRIPTION OF THE DRAWINGS

Example embodiments will be more clearly understood from the following detailed description taken in conjunction with the accompanying drawings. FIGS. 1 to 8 represent non-limiting, example embodiments as described herein.

FIG. 1 is a perspective view illustrating a wire bonding apparatus in accordance with some example embodiments;

FIG. 2 is a plan view illustrating the wire bonding apparatus in FIG. 1 in accordance with some example embodiments;

FIGS. 3 and 4 are plan views illustrating an operation of the wire bonding apparatus in FIG. 2 in accordance with some example embodiments;

FIG. 5 is a perspective view illustrating a wire bonding apparatus in accordance with some example embodiments;

FIG. 6 is a plan view illustrating the wire bonding apparatus in FIG. 5 in accordance with some example embodiments;

FIG. 7 is a perspective view illustrating a wire bonding apparatus in accordance with some example embodiments; and

FIG. 8 is a plan view illustrating the wire bonding apparatus in FIG. 7 in accordance with some example embodiments.

### DETAILED DESCRIPTION

Hereinafter, some example embodiments will be explained in detail with reference to the accompanying drawings. The same reference numerals are used for the same components in the drawings, and descriptions already given for them are omitted.

In order to clearly describe the present inventive concepts, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present inventive concepts are not necessarily limited to those illustrated in the drawings.

Throughout the specification, when a part is “connected” to another part, it includes not only a case where the part is “directly connected” but also a case where the part is “indirectly connected” with another part in between. In addition, unless explicitly described to the contrary, the word “comprise” and variations such as “comprises” or “comprising” will be understood to imply the inclusion of stated elements but not the exclusion of any other elements.

It will be understood that when an element is referred to as being “on” or “above” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

The use of the term “the” and similar demonstratives may correspond to both the singular and the plural. Operations constituting methods may be performed in any suitable order unless otherwise indicated herein or otherwise clearly contradicted by context and are not necessarily limited to the stated order.

The use of all illustrations or illustrative terms in some example embodiments is simply to describe the technical ideas in detail, and the scope of the present inventive concepts is not limited by the illustrations or illustrative terms unless they are limited by claims.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

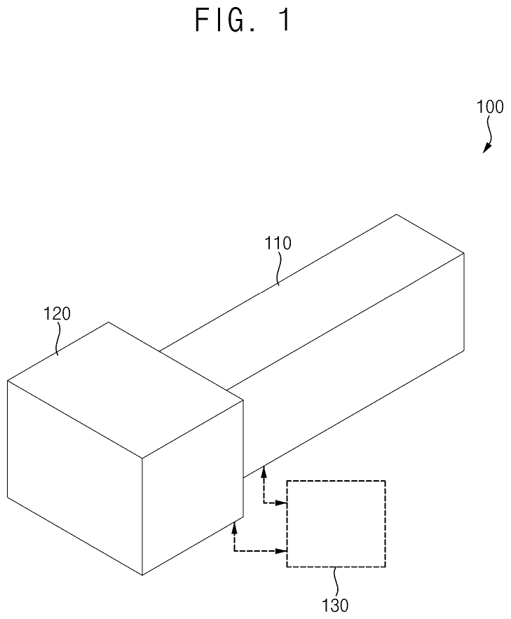

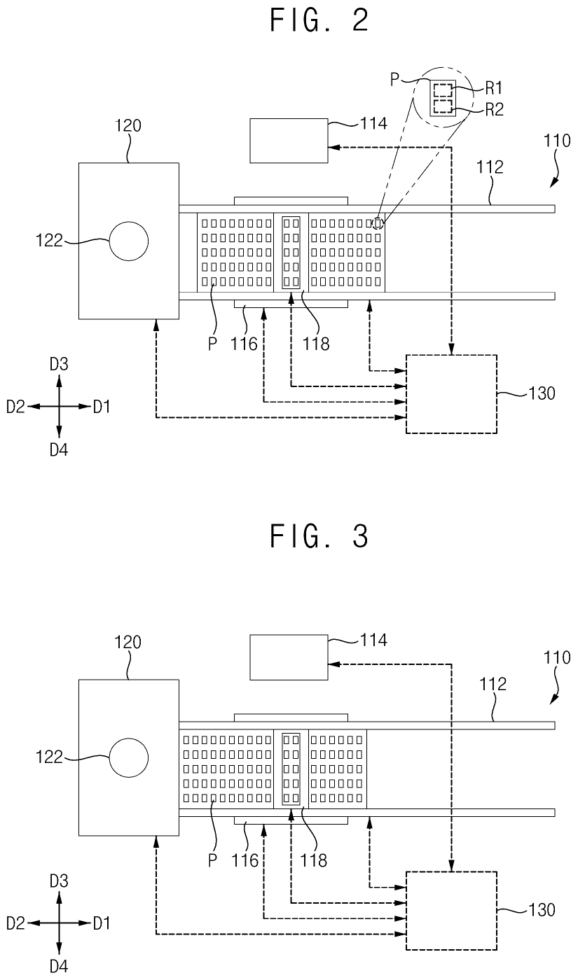

FIG. 1 is a perspective view illustrating a wire bonding apparatus in accordance with some example embodiments and FIG. 2 is a plan view illustrating the wire bonding apparatus in FIG. 1 in accordance with some example embodiments.

Referring to FIGS. 1 and 2, a wire bonding apparatus 100 of some example embodiments may include a bonder 110, a heater block 116, a window clamp 118 and a common loader/unloader 120.

The bonder 110 may bond a conductive wire to each of a plurality of package substrates P. Particularly, at least one semiconductor chip may be mounted on each of the package substrates P. The bonder 110 may bond the conductive wire to pads of the package substrate P and the semiconductor chip to electrically connect the package substrate P with the semiconductor chip. The conductive wire may include gold (Au) or aluminum (Al).

The bonder 110 may include a bonding rail 112 and a bonding head 114. The bonding rail 112 may be connected to the common loader/unloader 120. The bonding rail 112 may be extended from the common loader/unloader 120 in a first direction D1. Each of the package substrates P may be transferred on the bonding rail 112 in the first direction D1 (e.g., based on operation of the common loader/unloader 120). Further, each of the package substrates P may be transferred on the bonding rail 112 in a second direction D2 opposite to the first direction D1 (e.g., based on operation of the common loader/unloader 120). The common loader/unloader 120 may include an actuator, motor, driver, or the like that is configured to transfer one or more of the package substrates P on the bonding rail 112 in the first direction D1 and/or the second direction D2.

The bonding head 114 may be arranged over (e.g., on) the bonding rail 112. In FIG. 2, the bonding head 114 may be positioned at a side of the bonding rail 112. The bonding head 114 may bond the conductive wire to the package substrate P. In some example embodiments, the bonding head 114 may include a wire spool of conductive wire which is configured to release at least a portion of the conductive wire. In some example embodiments, the bonding head 114 may include a capillary configured to move in a horizontal direction and/or a vertical direction and configured to receive the conductive wire (e.g., from the wire spool) and further configured to press the wire against a portion of the package substrate (e.g., a pad of the package substrate). In some example embodiments, the bonding head 114 may include an electrode such as a torch electrode that may heat the wire pressed by the capillary to form a wire ball to be provided on a package substrate P (e.g., a pad thereof) and/or may cut the conductive wire. In some example embodiments, the bonding head 114 may include a wire tensioner (e.g., an air balloon holder, a pair of tongs, etc.) adjacent to the wire spool and configured to tension the conductive wire from the wire spool. In some example embodiments, the bonding head 114 may include a wire guide (e.g., a pulley) configured to withdraw wire from the wire tensioner (e.g., to form a loop). In some example embodiments, the bonding head 114 may include a wire clamp configured to hold or clamp the conductive wire for example when a wire ball is formed below the capillary. In some example embodiments, the bonding head 114 may include a tensioner (e.g., air balloon holder, pair of tongs, etc.) configured to tension the conductive wire held by the wire clamp. In some example embodiments, the bonding head 114 may include one or more drivers, drive motors, actuators, servomotors, or the like mechanically coupled to any of the aforementioned elements of the bonding head 114.

As shown in at least FIG. 2, each package substrate P may include a first region R1 and a separate, second region R2. In some example embodiments, the bonding head 114 may bond the conductive wire (e.g., an article, unit, etc. of the conductive wire) to a first region R1 of the package substrate P. Further, the bonding head 114 may bond the conductive wire (e.g., an article, unit, etc. of the conductive wire) to a second region R2 of the package substrate P except for the first region R1. For example, the bonding head 114 may bond a first article of conductive wire to the first region R1 of the package substrate P and not to the second region R2 of the package substrate P, and the bonding head 114 may bond a second article of conductive wire to the second region R2 of the package substrate P and not to the first region R1 of the package substrate P. The first region R1 may correspond to a left half region of the package substrate P, but example embodiments are not limited thereto. The second region R2 may correspond to a right half region of the package substrate P, but example embodiments are not limited thereto. That is, during a first portion of the bonding operation of the wire bonding apparatus 100, the package substrate P may be transferred on the bonding rail 112 in the first direction D1 (e.g., based on operation of the common loader/unloader 120), and the bonding head 114 may bond the conductive wire to the first region R1 of the package substrate P, i.e., the left half region of the package substrate P. In contrast, during a second, subsequent portion of the bonding operation of the wire bonding apparatus 100, the package substrate P may be transferred on the bonding rail 112 in the second direction D2 (e.g., based on operation of the common loader/unloader 120), and the bonding head 114 may bond the conductive wire to the second region R2 of the package substrate P, i.e., the right half region of the package substrate P.

The heater block 116 may be arranged under the bonding rail 112. The heater block 116 may heat the package substrate P during the bonding operation of the bonding head 114. The heater block 116 may include an electric resistive heater.

The window clamp 118 may be arranged over the bonding rail 112. The window clamp 118 may clamp the package substrate P during the bonding operation of the bonding head 114. The window clamp 118 may have a window configured to expose a bonding region of the package substrate P.

The common loader/unloader 120 may be positioned at only one side of the bonder 110. In some example embodiments, the common loader/unloader 120 may be arranged at a left side of the bonder 110, particularly, the bonding rail 112, but example embodiments are not limited thereto. For example, the common loader/unloader 120 may be arranged at a right side of the bonding rail 112.

The common loader/unloader 120 may load the package substrates P, particularly, a magazine configured to receive the package substrates P into the bonder 110. Further, the common loader/unloader 120 may unload the package substrates P with the conductive wire from the bonder 110. That is, the single common loader/unloader 120 may perform the loading operation and the unloading operation of the package substrate P. The common loader/unloader 120 may include a robot 122 (e.g., a mechanical actuator arm driven by one or more drivers or motors, for example one or more electrical servomotors or servoactuators) configured to load the package substrate P into the bonder 110 and to unload the package substrate P from the bonder 110.

As shown in at least FIGS. 1-2, in some example embodiments the wire bonding apparatus 100 may include a control device 130 which may be communicatively coupled (e.g., electrically coupled), for example via a wired or wireless connection, to some or all portions of the wire bonding apparatus 100 (e.g., the bonder 110, the single common loader/unloader 120, the robot 122, the rail 112, the bonding head 114, the heating block 116, the window claim 118 any portion thereof, or the like) and may be configured to control the wire bonding apparatus or any portions thereof to implement the functionality of the wire bonding apparatus 100 and/or any portions thereof (e.g., the bonder 110, the single common loader/unloader 120, the rail 112, the robot 122, the bonding head 114, the heating block 116, the window claim 118 any portion thereof, or the like), for example based on controlling a supply of electrical power to the wire bonding apparatus 100 and/or any portions thereof.

The control device 130 may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), a programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid-state drive memory device, storing a program of instructions, and a processor (e.g., CPU) configured to execute the program of instructions to implement the functionality and/or methods performed by some or all of the wire bonding apparatus 100, including for example the functionality and/or methods performed by the control device 130, the bonder 110, the single common loader/unloader 120, any portion thereof, or the like, according to any of the example embodiments.

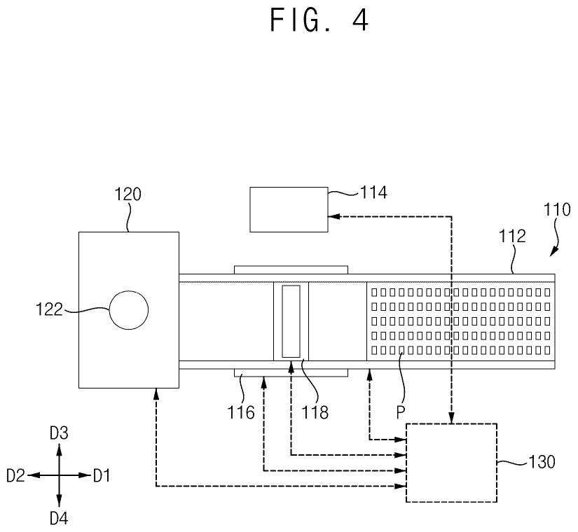

FIGS. 3 and 4 are plan views illustrating an operation of the wire bonding apparatus in FIG. 2 in accordance with some example embodiments. As described herein, operations of the wire bonding apparatus 100 may be implemented based on operation of a control device 130 of the wire bonding apparatus 100 (e.g., based on a processor executing a program of instructions stored on a memory to control one or more portions of the wire bonding apparatus 100 to which the control device 130 is communicatively coupled via a wired or wireless connection).

Referring to FIG. 3, the magazine with the package substrates P may be transferred to the common loader/unloader 120. The robot 122 may load each of the package substrates P into the bonder 110. The package substrate P may be transferred on the bonding rail 112 in the first direction D1. The bonding head 114 may bond the conductive wire to the left half region of the package substrate P.

Referring to FIG. 4, the package substrate P may be transferred on the bonding rail 112 in the second direction D2. The bonding head 114 may bond the conductive wire to the right half region of the package substrate P. The robot 122 may unload the package substrate P with the conductive wire from the bonder 110.

According to some example embodiments, the single common loader/unloader 120 may perform the load operation and the unload operation of the package substrate P. Thus, after the bonding head 114 may bond the conductive wire to the left half region of the package substrate P transferred in the first direction D1, the bonding head 114 may bond the conductive wire to the right half region of the package substrate P transferred in the second direction D2.

The wire bonding apparatus 100 of some example embodiments may not include an additional unloader (e.g., may not include any additional unloaders) so that the wire bonding apparatus 100 may have a length shorter than a length of a conventional wire bonding apparatus with the additional unloader, thereby reducing a size of the wire bonding apparatus 100 and thus improving productivity of semiconductor fabrication equipment, including the wire bonding equipment (e.g., with regard to space efficiency and/or compactness), for example such that an amount of semiconductor fabrication equipment in a given area may be increased due to the reduced size and thus reduced area of the wire bonding equipment including the wire bonding apparatus 100 in the given area.

Further, the wire bonding process may include transferring the package substrate P on the bonding rail 112 in the first direction D1 and transferring the package substrate P on the bonding rail 112 in the second direction D2. Thus, the bonding rail 112 may have a length shorter than a length of a bonding rail in the conventional wire bonding apparatus, thereby reducing a size of the wire bonding apparatus 100 and thus improving productivity of semiconductor fabrication equipment, including the wire bonding equipment (e.g., with regard to space efficiency and/or compactness), for example such that an amount of semiconductor fabrication equipment in a given area may be increased due to the reduced size and thus reduced area of the wire bonding equipment including the wire bonding apparatus 100 in the given area.

As a result, a total length of the wire bonding apparatus 100 may be shorter than a total length of the conventional wire bonding apparatus with the additional unloader so that the occupying area of the wire bonding apparatus 100 in the semiconductor fabrication equipment may be reduced to improve the productivity of the semiconductor fabrication equipment by the area (e.g., footprint of semiconductor fabrication equipment, including the wire bonding equipment, in a given area), for example such that an amount of semiconductor fabrication equipment in a given area may be increased due to the reduced size and thus reduced area of the wire bonding equipment including the wire bonding apparatus 100 in the given area.

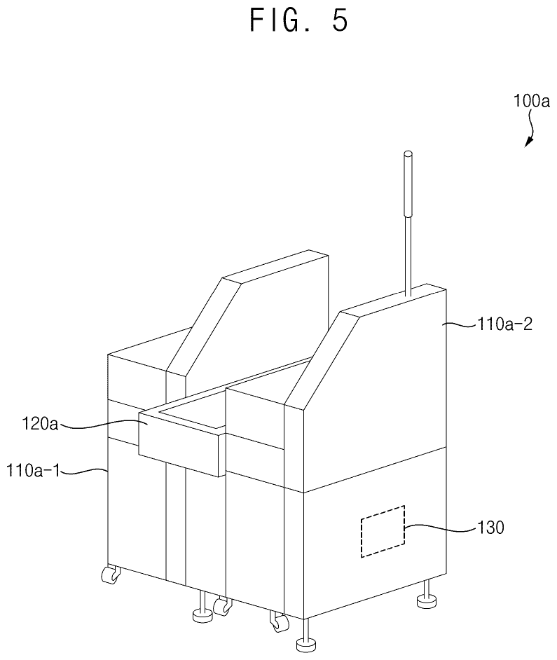

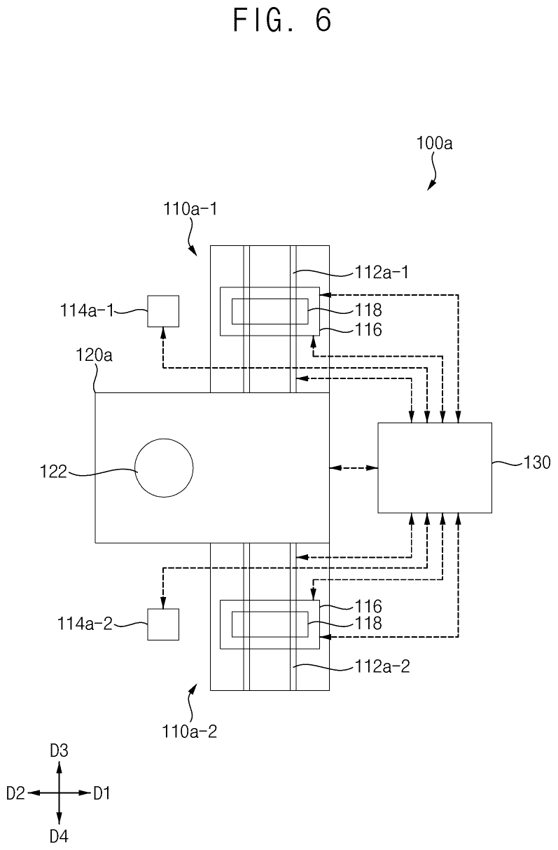

FIG. 5 is a perspective view illustrating a wire bonding apparatus in accordance with some example embodiments and FIG. 6 is a plan view illustrating the wire bonding apparatus in FIG. 5 in accordance with some example embodiments.

A wire bonding apparatus 100a of some example embodiments may include elements that are the same or substantially the same as elements of the wire bonding apparatus 100 in FIGS. 1 and 2 except for a bonder. Thus, the same reference numerals may refer to the same elements and any further illustrations with respect to the same elements may be omitted herein for brevity.

Referring to FIGS. 5 and 6, a wire bonding apparatus 100a of some example embodiments may include a first bonder 110a-1 and a second bonder 110a-2. The first bonder 110a-1 and the second bonder 110a-2 may be arranged at a front of the wire bonding apparatus 100a. Further, the first bonder 110a-1 and the second bonder 110a-2 may be spaced apart from each other along a third direction D3 perpendicular or substantially perpendicular to the first direction D1 and the second direction D2. The first bonder 110a-1 may bond the conductive wire (e.g., a first conductive wire, a first instance of the conductive wire, a first article of the conductive wire, a first unit of the conductive wire, etc.) to a first package substrate among the package substrates P. The second bonder 110a-2 may bond the conductive wire (e.g., a second conductive wire, a second instance of the conductive wire, a second article of the conductive wire, a second unit of the conductive wire, etc.) to a second package substrate among the package substrates P. Each of the first bonding 110a-1 and the second bonder 110a-2 may have a same or substantially same structure as described herein with regard to elements of the bonder 110. As shown, the control device 130 may be communicatively coupled to each of the first bonder 110a-1 and the second bonder 110a-2. The control device 130 may be configured to control, operate, etc., each of the first bonder 110a-1 and the second bonder 110a-2 to perform any of the functionality thereof as described herein.

A common loader/unloader 120a may be arranged between the first bonder 110a-1 and the second bonder 110a-2. The common loader/unloader 120a may load the first package substrate into the first bonder 110a-1. The common loader/unloader 120a may load the second package substrate into the second bonder 110a-2. Further, the common loader/unloader 120a may unload the first package substrate with the conductive wire from the first bonder 110a-1. The common loader/unloader 120a may unload the second package substrate with the conductive wire from the second bonder 110a-2. The common loader/unloader 120a may have a same or substantially same structure as described herein with regard to the common loader/unloader 120. The control device 130 may be configured to control, operate, etc. the common loader/unloader 120a to perform any of the functionality thereof as described herein.

The first bonder 110a-1 may include a first bonding rail 112a-1 and a first bonding head 114a-1. The common loader/unloader 120a may load the first package substrate into the first bonding rail 112a-1. As mentioned above, because the common loader/unloader 120a may be positioned between the first bonder 110a-1 and the second bonder 110a-2, a loading direction of the first package substrate into the first bonding rail 112a-1 by the common loader/unloader 120a may be the third direction D3. Thus, the first bonding rail 112a-1 may be extended in the third direction D3. Further, the first package substrate may be transferred on the first bonding rail 112a-1 in the third direction D3. The first package substrate may then be transferred on the first bonding rail 112a-1 in a fourth direction D4 opposite to the third direction D3.

The first bonding head 114a-1 may bond the conductive wire to the first package substrate. A bonding operation of the first bonding head 114a-1 may be substantially the same as the bonding operation of the bonding head 114 in FIG. 2. That is, the first bonding head 114a-1 may bond the conductive wire to the left half region of the first package substrate transferred on the first bonding rail 112a-1 in the third direction D3. Further, the first bonding head 114a-1 may bond the conductive wire to the right half region of the first package substrate transferred on the first bonding rail 112a-1 in the fourth direction D4.

The second bonder 110a-2 may include a second bonding rail 112a-2 and a second bonding head 114a-2. The common loader/unloader 120a may load the second package substrate into the second bonding rail 112a-2. As mentioned above, because the common loader/unloader 120a may be positioned between the first bonder 110a-1 and the second bonder 110a-2, a loading direction of the second package substrate into the second bonding rail 112a-2 by the common loader/unloader 120a may be the fourth direction D4. Thus, the second bonding rail 112a-2 may be extended in the fourth direction D4. Further, the second package substrate may be transferred on the second bonding rail 112a-2 in the fourth direction D4. The second package substrate may then be transferred on the second bonding rail 112a-2 in the third direction D3.

The second bonding head 114a-2 may bond the conductive wire to the second package substrate. A bonding operation of the second bonding head 114a-2 may be substantially the same as the bonding operation of the bonding head 114 in FIG. 2. That is, the second bonding head 114a-2 may bond the conductive wire to the left half region of the second package substrate transferred on the second bonding rail 112a-2 in the fourth direction D4. Further, the second bonding head 114a-2 may bond the conductive wire to the right half region of the second package substrate transferred on the second bonding rail 112a-2 in the third direction D3.

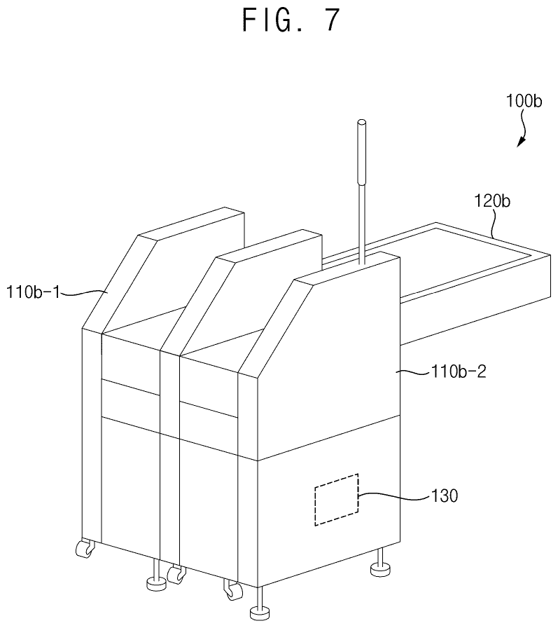

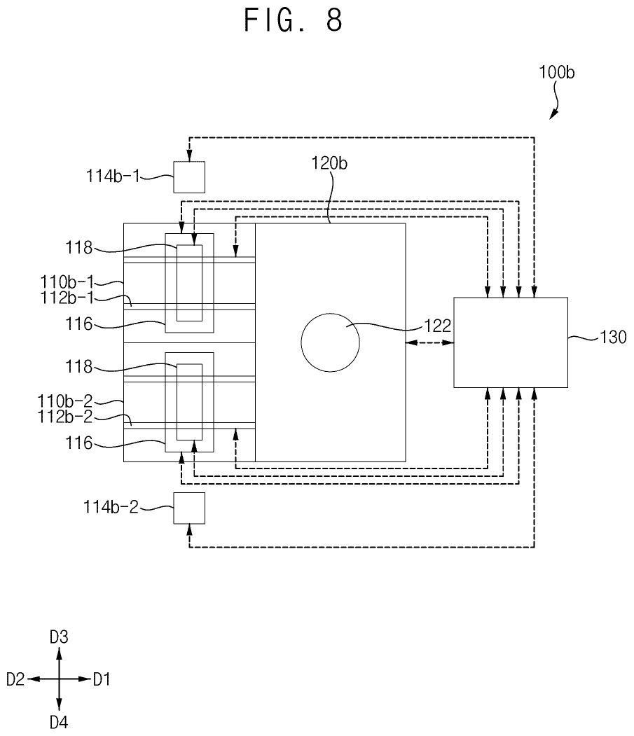

FIG. 7 is a perspective view illustrating a wire bonding apparatus in accordance with some example embodiments and FIG. 8 is a plan view illustrating the wire bonding apparatus in FIG. 7 in accordance with some example embodiments.

A wire bonding apparatus 100b of some example embodiments may include elements substantially the same as of the wire bonding apparatus 100 in FIGS. 1 and 2 except for a bonder. Thus, the same reference numerals may refer to the same elements and any further illustrations with respect to the same elements may be omitted herein for brevity.

Referring to FIGS. 7 and 8, a wire bonding apparatus 100b of some example embodiments may include a first bonder 110b-1 and a second bonder 110b-2. The first bonder 110b-1 and the second bonder 110b-2 may be arranged at a front of the wire bonding apparatus 100b. Further, a space may not be formed between the first bonder 110b-1 and the second bonder 110b-2. For example, the first bonder 110b-1 and the second bonder 110b-2 may be in direct contact with each other. The first bonder 110b-1 may bond the conductive wire to a first package substrate among the package substrates P. The second bonder 110b-2 may bond the conductive wire to a second package substrate among the package substrates P. Each of the first bonding 110b-1 and the second bonder 110b-2 may have a same or substantially same structure as described herein with regard to elements of the bonder 110. As shown, the control device 130 may be communicatively coupled to each of the first bonder 110b-1 and the second bonder 110b-2. The control device 130 may be configured to control, operate, etc., each of the first bonder 110b-1 and the second bonder 110b-2 to perform any of the functionality thereof as described herein.

A common loader/unloader 120b may be arranged at a rear region of the first bonder 110b-1 and the second bonder 110b-2. The common loader/unloader 120b may load the first package substrate into the first bonder 110b-1. The common loader/unloader 120b may load the second package substrate into the second bonder 110b-2. Further, the common loader/unloader 120b may unload the first package substrate with the conductive wire from the first bonder 110b-1. The common loader/unloader 120b may unload the second package substrate with the conductive wire from the second bonder 110b-2. The common loader/unloader 120b may have a same or substantially same structure as described herein with regard to the common loader/unloader 120. The control device 130 may be configured to control, operate, etc. the common loader/unloader 120b to perform any of the functionality thereof as described herein.

The first bonder 110b-1 may include a first bonding rail 112b-1 and a first bonding head 114b-1. The common loader/unloader 120b may load the first package substrate into the first bonding rail 112b-1. As mentioned above, because the common loader/unloader 120b may be positioned at the rear region of the first bonder 110b-1 and the second bonder 110b-2, a loading direction of the first package substrate into the first bonding rail 112b-1 by the common loader/unloader 120b may be the second direction D2. Thus, the first bonding rail 112b-1 may be extended in the second direction D2. Further, the first package substrate may be transferred on the first bonding rail 112b-1 in the second direction D2. The first package substrate may then be transferred on the first bonding rail 112b-1 in the first direction D1.

The first bonding head 114b-1 may bond the conductive wire to the first package substrate. A bonding operation of the first bonding head 114b-1 may be the same or substantially the same as the bonding operation of the bonding head 114 in FIG. 2. That is, the first bonding head 114b-1 may bond the conductive wire to the left half region of the first package substrate transferred on the first bonding rail 112b-1 in the second direction D2. Further, the first bonding head 114b-1 may bond the conductive wire to the right half region of the first package substrate transferred on the first bonding rail 112b-1 in the first direction D1.

The second bonder 110b-2 may include a second bonding rail 112b-2 and a second bonding head 114b-2. The common loader/unloader 120b may load the second package substrate into the second bonding rail 112b-2. As mentioned above, because the common loader/unloader 120b may be positioned at the rear region of the first bonder 110b-1 and the second bonder 110b-2, a loading direction of the second package substrate into the second bonding rail 112b-2 by the common loader/unloader 120b may be the second direction D2. Thus, the second bonding rail 112b-2 may be extended in the second direction D2. Further, the second package substrate may be transferred on the second bonding rail 112b-2 in the second direction D2. The second package substrate may then be transferred on the second bonding rail 112b-2 in the first direction D1.

The second bonding head 114b-2 may bond the conductive wire to the second package substrate. A bonding operation of the second bonding head 114b-2 may be the same or substantially the same as the bonding operation of the bonding head 114 in FIG. 2. That is, the second bonding head 114b-2 may bond the conductive wire to the left half region of the second package substrate transferred on the second bonding rail 112b-2 in the second direction D2. Further, the second bonding head 114b-2 may bond the conductive wire to the right half region of the second package substrate transferred on the second bonding rail 112b-2 in the first direction D1.

According to some example embodiments, the single common loader/unloader may load the package substrate into the bonder and unload the package substrate from the bonder (e.g., based on operating an actuator arm, an actuator device, or the like). The common loader/unloader may be positioned at one side of the bonder so that the wire bonding apparatus may have a short length. As a result, an occupying area of the wire bonding apparatus in semiconductor fabrication equipment may be reduced to improve a productivity of the semiconductor fabrication equipment.

The foregoing is illustrative of some example embodiments and is not to be construed as limiting thereof. Although some example embodiments have been described, those skilled in the art will readily appreciate that many modifications are possible in the example embodiments without departing from the novel teachings and advantages of the present inventive concepts. Accordingly, all such modifications are intended to be included within the scope of the present inventive concepts as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments described, and that modifications to the described example embodiments, as well as other example embodiments, are intended to be included within the scope of the appended claims.

What is claimed is:

1. A wire bonding apparatus, comprising:
a bonder configured to bond a conductive wire to a plurality of package substrates; and
a common loader/unloader configured to load the plurality of package substrates into the bonder and to unload the plurality of package substrates from the bonder.

2. The wire bonding apparatus of claim 1, wherein the bonder comprises:
a bonding rail connected to the common loader/unloader, the bonding rail configured to transfer the plurality of the plurality of package substrates; and
a bonding head over the bonding rail, the bonding head configured to bond the conductive wire to the plurality of the plurality of package substrates.

3. The wire bonding apparatus of claim 2, wherein
the bonding head is configured to bond the conductive wire to a first region of each package substrate of the plurality of package substrates, and
the bonding head is configured to bond the conductive wire to a second region of each package substrate of the plurality of package substrates except for the first region.

4. The wire bonding apparatus of claim 3, wherein, in each package substrate of the plurality of package substrates,
the first region corresponds to a half region of the package substrate, and
the second region corresponds to a remaining half region of the package substrate.

5. The wire bonding apparatus of claim 1, wherein the bonder comprises:
a first bonder configured to bond a first article of the conductive wire to a first package substrate among the plurality of package substrates; and
a second bonder configured to bond a second article of the conductive wire to a second package substrate among the plurality of package substrates.

6. The wire bonding apparatus of claim 5, wherein the first bonder comprises:
a first bonding rail configured to transfer the first package substrate; and
a first bonding head over the first bonding rail, the first bonding head configured to bond the first article of the conductive wire to the first package substrate.

7. The wire bonding apparatus of claim 5, wherein the second bonder comprises:
a second bonding rail configured to transfer the second package substrate; and
a second bonding head over the second bonding rail, the second bonding head configured to bond the second article of the conductive wire to the second package substrate.

8. The wire bonding apparatus of claim 5, wherein the common loader/unloader is between the first bonder and the second bonder.

9. The wire bonding apparatus of claim 8, wherein
the common loader/unloader is configured to load the first and second package substrates into the first and second bonders, and
the common loader/unloader is configured to unload the first and second package substrates from the first and second bonders.

10. The wire bonding apparatus of claim 5, wherein the common loader/unloader is at a rear region of the first and second bonders.

11. The wire bonding apparatus of claim 10, wherein the common loader/unloader comprises a robot configured to
load the first and second package substrates into the first and second bonders, and
unload the first and second package substrates from the first and second bonders.

12. The wire bonding apparatus of claim 1, wherein the bonder comprises:
a heater block configured to heat each package substrate of the plurality of package substrates; and
a window clamp configured to clamp each package substrate of the plurality of package substrates.

13. A wire bonding apparatus, comprising:
a first bonder configured to bond a first article of a conductive wire to a first package substrate;
a second bonder configured to bond a second article of the conductive wire to a second package substrate; and
a common loader/unloader between the first bonder and the second bonder, the common loader/unloader configured to
load the first and second package substrates into the first and second bonders, and
unload the first and second package substrates from the first and second bonders.

14. The wire bonding apparatus of claim 13, wherein the first bonder comprises:
a first bonding rail configured to transfer the first package substrate; and
a first bonding head over the first bonding rail, the first bonding head configured to bond the first article of the conductive wire to the first package substrate.

15. The wire bonding apparatus of claim 13, wherein the second bonder comprises:
a second bonding rail configured to transfer the second package substrate; and
a second bonding head over the second bonding rail, the second bonding head configured to bond the second article of the conductive wire to the second package substrate.

16. The wire bonding apparatus of claim 13, wherein the common loader/unloader comprises a robot configured to
load the first and second package substrates into the first and second bonders, and
unload the first and second package substrates from the first and second bonders.

17. The wire bonding apparatus of claim 13, wherein each of the first and second bonders comprises:
a heater block configured to heat the first and second package substrates; and
a window clamp configured to clamp the first and second package substrates.

18. A wire bonding apparatus, comprising:
a first bonder configured to bond a first article of a conductive wire to a first package substrate;
a second bonder configured to bond a second article of the conductive wire to a second package substrate; and
a common loader/unloader at a rear region of the first bonder and the second bonder, the common loader/unloader configured to
load the first and second package substrates into the first and second bonders, and
unload the first and second package substrates from the first and second bonders.

19. The wire bonding apparatus of claim 18, wherein the first bonder comprises:
a first bonding rail configured to transfer the first package substrate; and
a first bonding head over the first bonding rail, the first bonding head configured to bond the first article of the conductive wire to the first package substrate.

20. The wire bonding apparatus of claim 18, wherein the second bonder comprises:
a second bonding rail configured to transfer the second package substrate; and
a second bonding head over the second bonding rail, the second bonding head configured to bond the second article of the conductive wire to the second package substrate.
